(19) United States
(12) Patent Application Publication
(10) Pub. No.: US 2026/0198003 A1
(43) Pub. Date: Jul. 9, 2026

(54) METHODS OF MANUFACTURING AN ELECTRONIC CIRCUIT HAVING AIR GAPS BETWEEN CONDUCTIVE LINES

(71) Applicant: MICRON TECHNOLOGY, INC., Boise, ID (US)

(72) Inventors: Sandeep Ramasamudra Suresha, Round Rock, TX (US); Indra Vaishnavi Chary, Boise, ID (US)

(21) Appl. No.: 19/010,503

(22) Filed: Jan. 6, 2025

(51) Int. Cl. H10B 43/20; H10B 41/20

(52) U.S. Cl. CPC H10B 43/20; H10B 41/20

(57) ABSTRACT

A method includes forming a plurality of conductive lines on a substrate. Each of the plurality of conductive lines include a metal layer and a nitride layer. The method further includes depositing a nitride spacer layer on the plurality of conductive lines. The method further includes filling a plurality of gaps between the plurality of conductive lines by depositing an oxide layer between the plurality of conductive lines. The method further includes forming a plurality of air gaps between the plurality of conductive lines by removing the nitride spacer layer.

### TECHNICAL FIELD

Embodiments of the disclosure relate generally to memory sub-systems, and more specifically, relate to methods of manufacturing an electronic circuit having air gaps.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-I are cutaway schematic representations illustrating a method of manufacturing an electronic having air gaps between conductive lines, in accordance with some embodiments of the present disclosure.

FIGS. 2A-B are cutaway schematic representations illustrating processes of a method of manufacturing an electronic circuit having air gaps between conductive lines, in accordance with some embodiments of the present disclosure.

FIGS. 3A-B are flow diagrams of example methods of manufacturing an electronic circuit having air gaps between conductive lines, in accordance with some embodiments of the present disclosure.

FIG. 4A illustrates an example computing system that includes a memory sub-system in accordance with some embodiments of the present disclosure.

FIG. 4B is a block diagram of a memory device in communication with a memory sub-system controller of a memory sub-system, according to an embodiment.

### DETAILED DESCRIPTION

Aspects of the present disclosure are directed to methods of manufacturing an electronic circuit (e.g., a memory array) having air gaps. Storage devices such as solid-state drives (SSDs) may incorporate 3-dimensional (3D) NAND flash memory technology. Traditional NAND flash memory stores data in a 2-dimensional (2D) structure, where memory cells are laid out on a single layer. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers. In order to achieve higher storage capacities and/or improve performance of the device, the number of tiers within a single memory device may be increased, thus allowing for higher-capacity storage devices. However, the increase in the number of tiers also increases the overall height of the 3D NAND structure. “Height” herein refers to the size of the 3D NAND structure that is measured in the direction that is orthogonal to the layers substantially forming the structure. To limit the height of the 3D NAND structure, the thickness of each tier can be decreased.

A 3D NAND device includes conductive lines, such as bitlines for accessing memory cells in a memory array of the device. Performance of a memory array may be at least partially dependent upon the capacitance between bitlines. For example, delays in programming are introduced when capacitance between bitlines is high. The introduced delays reduce the likelihood of mis-programming memory cells. Therefore, the duration of a memory cell programming operation may be related to the capacitance between bitlines. A decrease in the capacitance between bitlines may decrease the delay, and therefore may decrease the duration of the programming operations performed with respect to the associated memory cells. Performance of a memory cell may be increased accordingly if capacitance between bitlines is reduced.

In some embodiments, air gaps are formed in a memory array structure (e.g., a 3D NAND structure, etc.) between conductive lines (e.g., bitlines) so that capacitance between neighboring conductive lines is reduced. Some memory arrays do not have air gaps between conductive lines, leading to increased capacitance on the conductive lines and corresponding decreased memory array performance. However, some memory arrays having air gaps between conductive lines may be susceptible to electrical shorts between neighboring conductive lines. In some embodiments, by including an air gap between conductive lines formed using the method(s) disclosed herein, capacitance between conductive lines and/or susceptibility to electrical shorting can be reduced without risk of shorting between neighboring conductive lines, leading to increased memory array performance.

Aspects of the present disclosure may address the deficiencies described above and other challenges by providing methods of manufacturing a memory array having air gaps between conductive lines. Like discussed herein above, inclusion of air gaps between conductive lines can increase the performance of a memory array by decreasing the capacitance of conductive lines with respect to neighboring conductive lines and/or by decreasing the likelihood of electrical shorting between neighboring conductive lines. In some embodiments, air gaps are formed between conductive lines by performing a series of process operations. The conductive lines may be bitlines of a memory array. The conductive lines may be formed on a substrate, such as an oxide substrate. Metal contacts within the substrate may connect the conductive lines (e.g., bitlines, etc.) to memory cells of the memory array. In some embodiments, a nitride spacer layer (e.g., a metalloid nitride layer such as a silicon nitride layer, etc.) is deposited on the conductive lines. The nitride spacer layer may be a sacrificial layer that is later removed to form the air gaps between conductive lines. In some embodiments, gaps between the conductive lines (having the nitride spacer layer deposited thereon) are filled by depositing an oxide layer between the conductive lines. The oxide layer may be a metalloid oxide layer (e.g., such as a silicon oxide layer, etc.). The nitride spacer layer may be removed, such as by a selective etch operation (e.g., an operation to etch the nitride spacer layer selective to the oxide layer, etc.) to form the air gaps between the conductive lines. Another oxide layer may be deposited on top of the conductive lines and air gaps. Metal contacts may be formed within the oxide layer to electrically couple to the conductive lines.

Advantages of the present disclosure include, for example, improved 3D NAND performance. For example, and as described herein, inclusion of air gaps between bitlines (e.g., conductive lines, etc.) decreases the capacitance between bitlines. A decrease in capacitance between bitlines allows for a decrease in delay for programming memory cells, such as read or write operations, without sacrificing program accuracy. Therefore, the time for programming the memory cells can be decreased and memory array performance is thus increased. Moreover, as described herein, inclusion of air gaps between bitlines may reduce the likelihood of electrical shorting between neighboring bitlines. Fewer electrical shorts may also lead to increased memory array performance. Accordingly, a 3D NAND device manufactured according to methods described herein may have increased performance when compared to other devices.

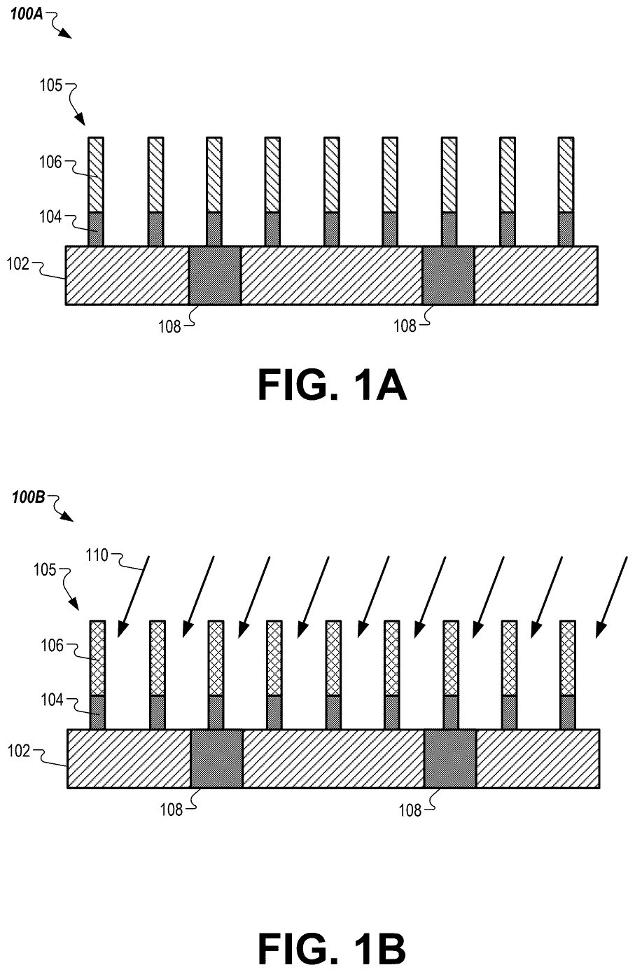

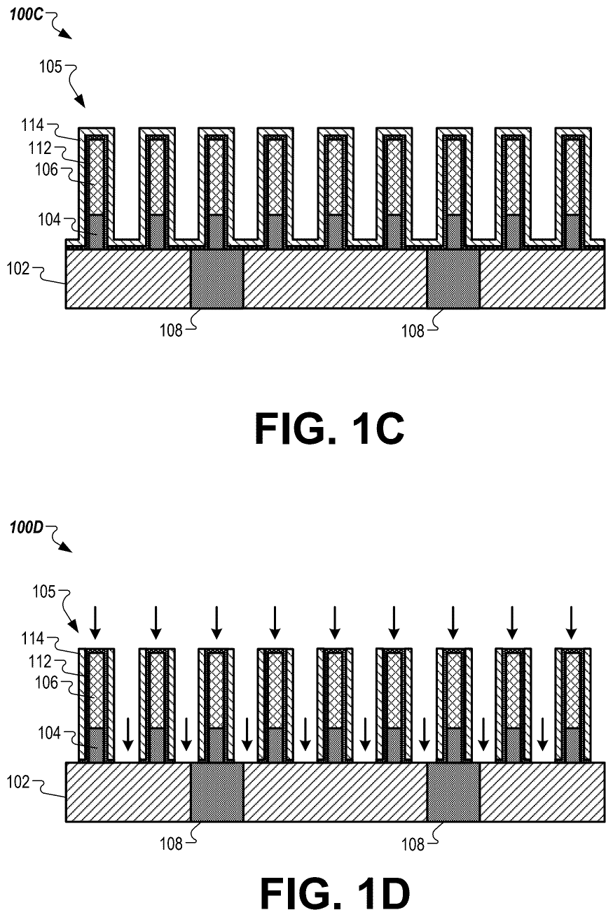

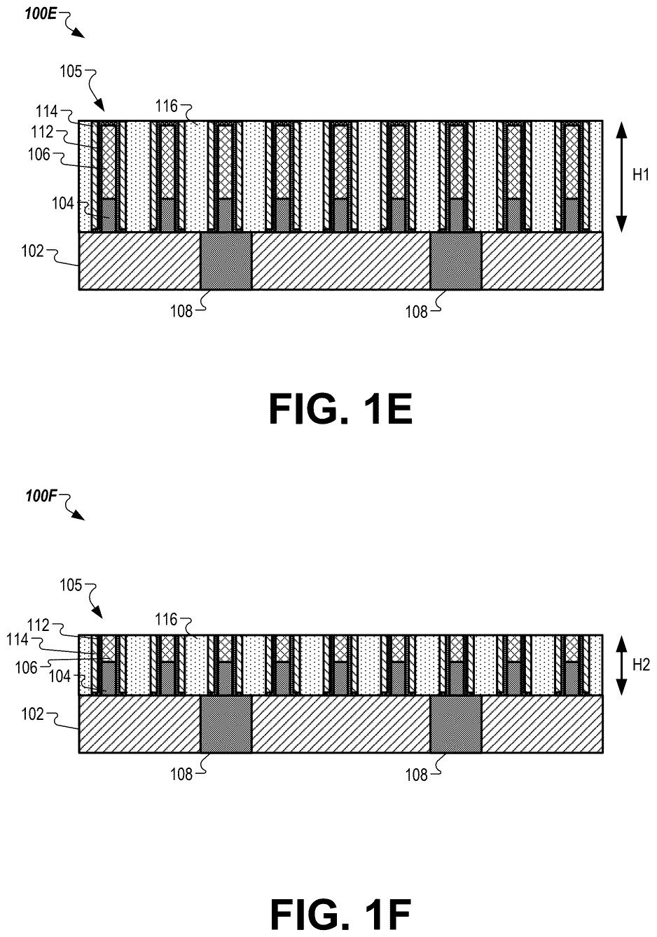

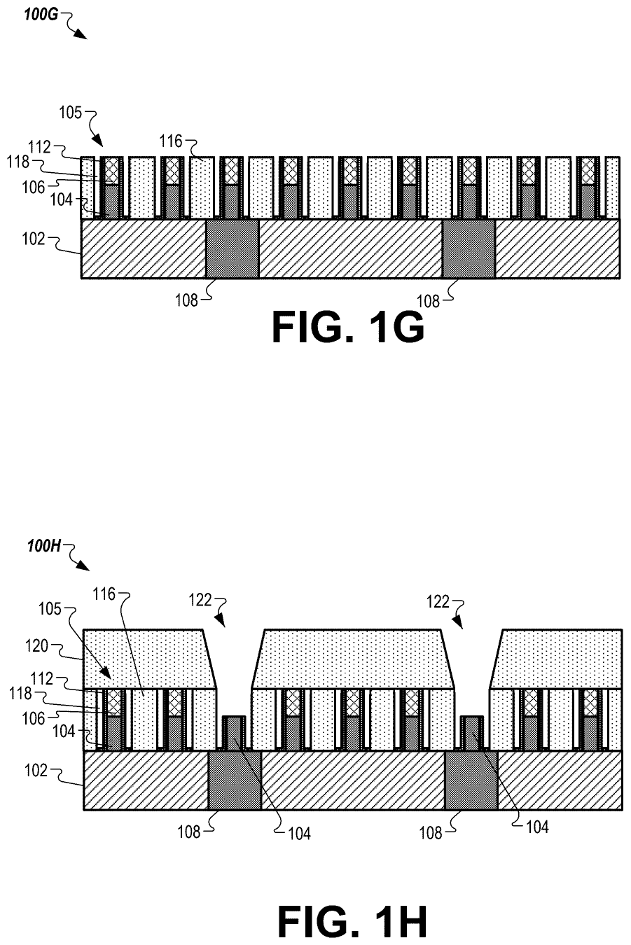

FIGS. 1A-I are cutaway schematic representations illustrating a method of manufacturing an electronic having air gaps between conductive lines, in accordance with some embodiments of the present disclosure. In some embodiments, each of FIGS. 1A-I illustrate a manufacturing operation for manufacturing a memory array as described herein.

Referring to FIG. 1A, a representation of an operation 100A is shown. In some embodiments, a plurality of conductive lines 105 are formed on a substrate 102. The substrate 102 may be an oxide base layer, such as a metalloid oxide (e.g., silicon oxide, etc.) base layer. The conductive lines 105 may be bitlines, such as for a memory array (e.g., of a 3D NAND device, etc.). Each of the conductive lines 105 may include a metal layer 104 and a nitride layer 106. The metal layer 104 may include a conductive metal such as tungsten or a tungsten alloy, etc. The nitride layer 106 may be a metalloid nitride layer (e.g., silicon nitride, etc.). The substrate 102 may include multiple metal contacts 108 that connect to the metal layer 104 of conductive lines 105. The conductive lines 105 may be formed substantially orthogonal to the substrate 102. In some embodiments, the conductive lines 105 are formed by deposition, patterning, and/or etch processes.

Referring to FIG. 1B, a representation of an operation 100B is shown. In some embodiments, the nitride layers 106 are doped with a dopant 110. The dopant 110 may include carbon. In some embodiments, the nitride layers 106 are doped with carbon to form carbon-doped metalloid nitride layers. Doping the nitride layer 106 with carbon may cause later selective etch operations to etch other nitride layer(s) without etching the nitride layer 106. For example, a later etch operation may be performed to etch nitride selective to one or more other material compositions, such as carbon-doped nitride and/or oxide, etc. Because the nitride layer 106 may be doped with carbon, the selective etch operation (to etch nitride, etc.) may not affect the carbon-doped nitride layer 106.

Referring to FIG. 1C, a representation of an operation 100C is shown. In some embodiments, protective liners 112 are deposited on the conductive lines 105. The protective liners 112 may be oxide liners (e.g., metalloid oxide liners such as silicon oxide liners, etc.) deposited on the conductive lines 105 and/or encapsulating the conductive lines 105. In some embodiments, the protective liners 112 include a metalloid oxide having a dielectric constant that is less than a threshold value (e.g., the protective liners 112 include a low-K oxide, etc.). For example, the protective liners 112 may include an oxide having a dielectric constant K that is less than approximately 3.9. In some embodiments, the protective liners 112 are deposited to protect the conductive lines 105, such as during one or more subsequent etch operations. In some embodiments, a spacer layer 114 is deposited on the protective liners 112 on the conductive lines 105. The spacer layer 114 may be a nitride layer (e.g., a metalloid nitride layer such as silicon nitride layer, etc.). In some embodiments, the spacer layer 114 is a sacrificial layer and may be at least partially removed in one or more subsequent process operations. The thickness of the spacer layer 114 may define the size of air gaps formed in one or more subsequent operations described herein below. For example, depositing a thicker spacer layer 114 may allow for larger air gaps, while depositing a thinner spacer layer 114 may allow for narrower air gaps, etc. In some embodiments, the protective liners 112 and/or the spacer layer 114 may be conformal layers deposited on the conductive lines 105. After the protective liners 112 and the spacer layer 114 are deposited on the conductive lines 105, there may be multiple gaps between the conductive lines 105. The multiple gaps may be filled during one or more subsequent process operations described herein below.

Referring to FIG. 1D, a representation of an operation 100D is shown. In some embodiments, portions of the spacer layer 114 are removed between the conductive lines 105 and/or on top of the conductive lines 105. Portions of the protective liners 112 may be removed between the conductive lines 105. In some embodiments, an anisotropic etch operation is performed to etch the spacer layer 114. For example, and in some embodiments, a dry etch process is performed to etch the spacer layer 114 in a downward direction. Thus, only horizontal portions (as illustrated) of the spacer layer 114 may be etched. In some embodiments, the etch operation etches nitride selective to oxide. For example, the nitride layer (e.g., spacer layer 114) may be etched without etching the oxide substrate 102 so that the nitride layer is removed from the tops of the conductive lines 105 and from the substrate 102 in the gaps between the conductive lines 105.

Referring to FIG. 1E, a representation of an operation 100E is shown. In some embodiments, the gaps between the conductive lines 105 are filled by depositing an oxide layer 116 between the conductive lines 105. The oxide layer 116 may be a metalloid oxide layer, such as a silicon oxide layer, etc. The oxide layers 116 may be deposited such that a top of the oxide layer 116 approximately corresponds to the tops of conductive lines 105. In some embodiments, at operation 100E, the deposited oxide layer 116 and the conductive lines 105 have a first height H1.

Referring to FIG. 1F, a representation of an operation 100F is shown. In some embodiments, the height of the conductive lines 105 (with protective liner 112 and spacer layer 114 deposited thereon) and the height of the oxide layer 116 is reduced to height H2. The height of the conductive lines 105 and/or the oxide layer 116 may be reduced by a planarization process. In some embodiments, a chemical-mechanical planarization process (e.g., a CMP process) is performed with respect to the conductive lines 105 and the oxide layer 116 to reduce an overall height of the conductive lines 105 and the oxide layer 116 to height H2. The CMP process may be a buff CMP process. In some embodiments, height H2 is between approximately 30 nanometers and approximately 70 nanometers less than height H1. In some embodiments, height H2 is approximately 50 nanometers less than height H1.

Referring to FIG. 1G, a representation of an operation 100G is shown. In some embodiments, air gaps 118 are formed between each of the conductive lines by removing the spacer layer 114. Removing the spacer layer 114 may form voids in the oxide layer 116. The voids may correspond to the air gaps 118. In some embodiments, the spacer layer is removed by performing a selective etch operation with respect to the spacer layer 114. For example, and in some embodiments, an etch operation may be performed to etch nitride selective to oxide. During the selective etch operation, the nitride spacer layer 114 may be etched while the oxide layer 116 and the protective oxide liners 112 are not etched. The protective oxide liners 112 may protect the nitride layer 106 and/or the metal layer 104 from being damaged during the etch operation. In some embodiments, the spacer layer 114 is etched using a hot-phosphorous etch process. The hot phosphorous etch process may include introducing a hot solution of phosphoric acid (H₃PO₄) to the spacer layer 114. The hot solution of phosphoric acid may have a high selectivity for the nitride of the spacer layer 114 over the oxide of the oxide layer 116 and/or the oxide of the protective liners 112. The hot solution of phosphoric acid may be introduced to the spacer layer 114 at an elevated temperature, such as a temperature between approximately 150 and approximately 180 degrees Celsius.

Referring to FIG. 1H, a representation of an operation 100H is shown. In some embodiments, another oxide layer 120 is deposited on top of the oxide layer 116 and on top of the conductive lines 105. In some embodiments, the oxide layer 120 is deposited by a chemical-vapor deposition (CVD) process so that the oxide layer 120 does not fill the air gaps 118. In some embodiments, holes 122 are formed through the oxide layer 120 to expose at least a subset of the conductive lines 105. The holes 122 may be formed through the oxide layer 120 with a tapered profile. For example, the holes 122 may be formed having a larger width at the top of the hole than at the bottom of the hole. The respective nitride layers 106 of the exposed conductive lines 105 may be removed, such as by performance of an etch operation (e.g., a selective etch operation, etc.). The etch operation may be performed to etch nitride (e.g., carbon-doped nitride, etc.) selective to oxide.

Referring to FIG. 1I, a representation of an operation 100I is shown. In some embodiments, the holes 122 are filled with a metal 124 to form metal contacts. The metal may fill the holes 122 and/or the respective air gaps 118 of the exposed conductive lines 105. The metal contacts may be to electrically connect a CMOS layer (e.g., above the metal 124, not illustrated) to the metal layer 104 of a subset of conductive lines 105. Additional metal contacts 108 formed in the substrate 102 may connect the metal layers 104 to memory cells of the memory array. In some embodiments, the metal 124 is an electrically conductive metal such as tungsten or a tungsten alloy. The air gaps 118 may be disposed between the conductive lines 105. In some embodiments, sides of the air gaps 118 are defined by the oxide layer 116 and tops of the air gaps 118 are defined by the oxide layer 120. In some embodiments, the air gaps 118 are defined by a surface of the protective oxide liner 112 and a inner surface of the oxide layer 116. The air gaps 118 may be further defined by a surface of the oxide layer 120 and/or a surface of the substrate 102.

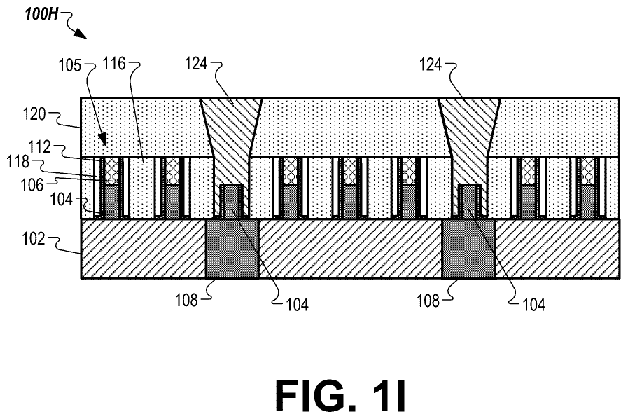

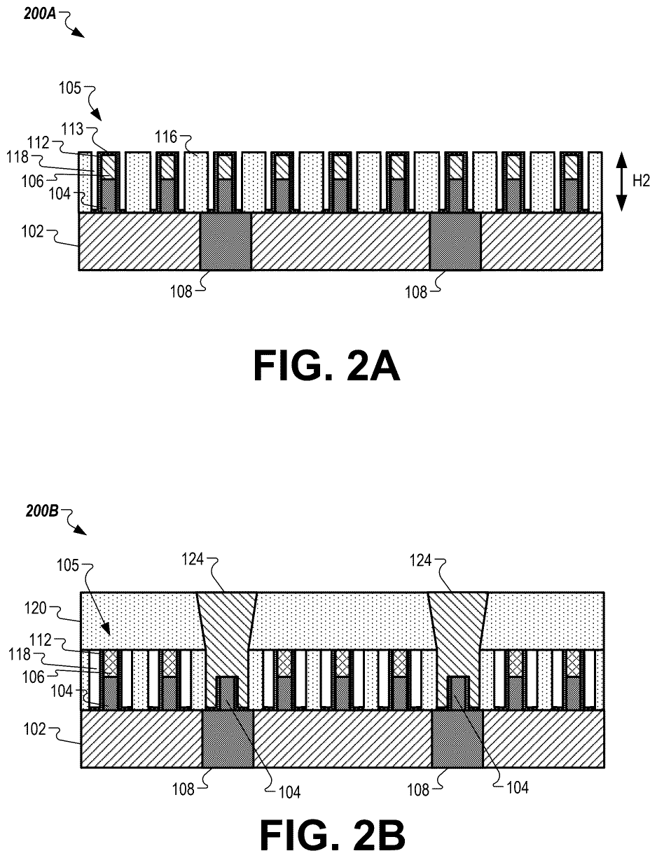

FIGS. 2A-B are cutaway schematic representations illustrating processes of a method of manufacturing an electronic circuit having air gaps between conductive lines, in accordance with some embodiments of the present disclosure. In some embodiments, each of FIGS. 2A-B illustrate a manufacturing operation for manufacturing a memory array as described herein. In some embodiments, each of FIGS. 2A-B illustrate an alternate process to at least one of the processes illustrated in one of FIGS. 1A-I.

Referring to FIG. 2A, a representation of an operation 200A is shown. In some embodiments, the conductive lines 105 are formed having a height H2. Height H2 may be between approximately 40 nanometers and approximately 70 nanometers. By forming the conductive lines 105 (and the oxide layer 116) having height H2, a CMP process to reduce the height of the conductive lines 105 and/or the oxide layer 116 can be eliminated. In some embodiments, the protective oxide liners 112 are deposited on the conductive lines 105. In some embodiments, the nitride layer 106 is not doped (e.g., is not carbon-doped, etc.). By not doping the nitride layer 106, a doping process can be eliminated from the overall process flow. The protective oxide liners 112 may protect both the nitride layer 106 and the metal layer 104, such as from an etch process to remove a spacer layer 114 to form air gaps 118.

Referring to FIG. 2B, a representation of an operation 200B is shown. In some embodiments, the size (i.e., thickness, etc.) of the air gaps 118 is determined by the thickness of the spacer layer 114 deposited at operation 100C. For example, depositing a thicker spacer layer 114 may allow for larger air gaps 118, while depositing a thinner spacer layer 114 may allow for narrower air gaps 118, etc. Comparing FIG. 2B to FIG. 1I, the air gaps 118 shown in FIG. 2B may be larger (e.g., thicker, etc.) than the air gaps 118 shown in FIG. 1I. The larger air gaps 118 may be possible due at least in part to depositing a thicker spacer layer 114. In some embodiments, larger air gaps reduce the capacitance between conductive lines 105 (e.g., bitlines, etc.) more than smaller air gaps, allowing for improved memory array performance. In some embodiments, larger air gaps 118 also allow for larger metal contacts to be formed by the metal 124 for contacting the metal layer 104 of the exposed conductive lines 105.

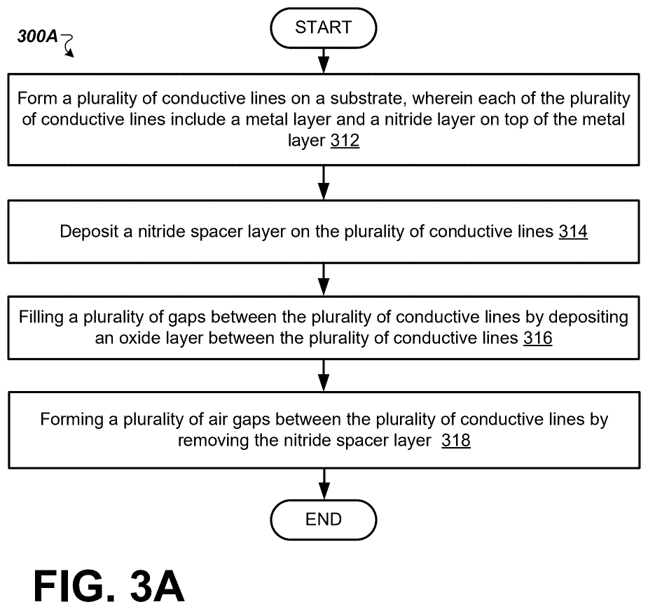

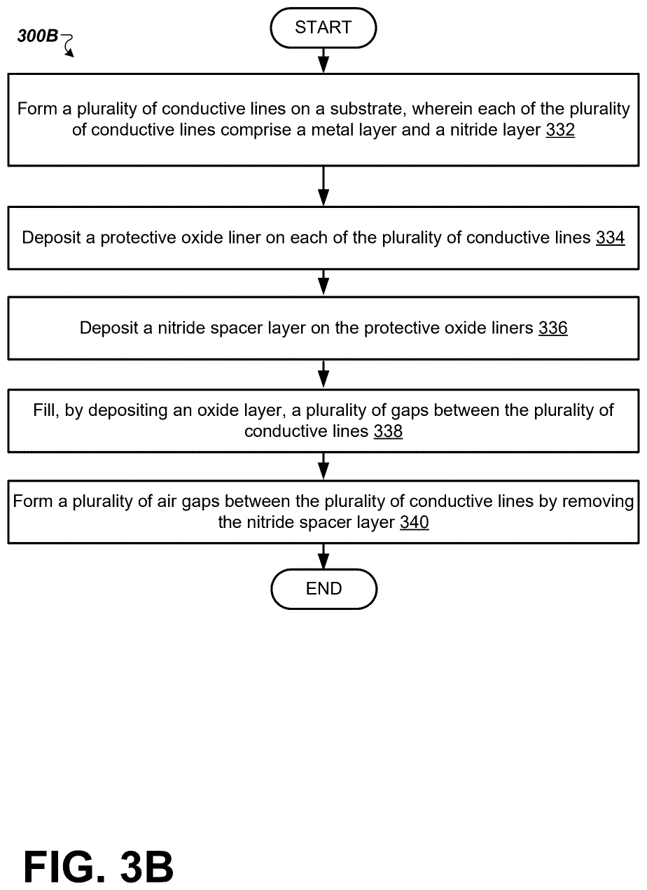

FIGS. 3A-B are flow diagrams of example methods of manufacturing an electronic circuit having air gaps between conductive lines, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 3A, a flow diagram of an example method 300A is shown. At block 312, a plurality of conductive lines are formed on a substrate. The substrate may be an oxide substrate (e.g., a metalloid oxide substrate such as a silicon oxide substrate, etc.). In some embodiments, the conductive lines are bitlines, such as bitlines of a memory device (e.g., a 3D NAND device, etc.). The plurality of conductive lines may be formed substantially orthogonal to the surface of the substrate. The plurality of conductive lines may be formed with gaps between the conductive lines. In some embodiments, each of the plurality of conductive lines include a metal layer and a nitride layer on top of the metal layer. The metal layer may be made of an electrically conductive metal such as tungsten or a tungsten alloy. The nitride layer may be a metalloid nitride layer such as a silicon nitride layer. In some embodiments, the nitride layer is doped, such as with carbon. For example, the nitride layer may be a carbon-doped silicon nitride layer.

At block 314, a nitride spacer layer is deposited on the plurality of conductive lines. The nitride spacer layer may be a conformal layer deposited on the conductive lines. In some embodiments, the nitride spacer layer is a metalloid nitride (e.g., silicon nitride, etc.) spacer layer. The nitride spacer layer may be deposited on protective oxide liners that are deposited on the conductive lines. In some embodiments, the nitride spacer layer is a sacrificial layer that may be removed during one or more subsequent process operations. In some embodiments, the thickness of the nitride spacer layer determines the size (e.g., thickness, etc.) of air gaps formed between the conductive lines in one or more subsequent process operations. For example, a thicker nitride spacer layer may allow for larger (e.g., thicker, etc.) air gaps while a thinner nitride spacer layer may allow for smaller (e.g., thinner, etc.) air gaps.

At block 316, a plurality of gaps between the plurality of conductive lines are filled by depositing an oxide layer between the plurality of conductive lines. The oxide layer may be a metalloid oxide layer (e.g., a silicon oxide layer, etc.). In some embodiments, the oxide layer is deposited by CVD or another suitable deposition process. The oxide layer may be deposited on the nitride spacer layer between the conductive lines.

At block 318, a plurality of air gaps are formed between the plurality of conductive lines by removing the nitride spacer layer. A selective etch process may be performed. In some embodiments, the selective etch operation etches nitride selective to oxide to etch the nitride spacer layer without damaging the oxide layer deposited at block 316. For example, the spacer layer may be etched away without etching the oxide layer. In some embodiments, a hot-phosphorous etch operation is performed with respect to the nitride spacer layer to remove the nitride spacer layer. Air gaps may be formed in the voids left by the removed nitride spacer layer. The thickness of the air gaps may be determined by the thickness of the nitride spacer layer. For example, a thicker nitride spacer layer, when removed, may leave larger voids, corresponding to larger air gaps. A thinner nitride spacer layer, when removed, may leave smaller voids, corresponding to smaller air gaps.

Referring to FIG. 3B, a flow diagram of an example method 300B is shown. At block 332, a plurality of conductive lines (e.g., bitlines, etc.) are formed on a substrate. Each of the plurality of conductive lines may include a metal layer and a nitride layer. The nitride layer may be formed on top of the metal layer. In some embodiments, the substrate is an oxide substrate (e.g., a metalloid oxide substrate, etc.). In some embodiments, the nitride layer is doped, such as with carbon, to form a carbon-doped nitride layer. In other embodiments, the nitride layer is not doped.

At block 334, a protective oxide liner is deposited on each of the plurality of conductive lines. The protective oxide liner may be a metalloid oxide liner, such as a silicon oxide liner. The protective oxide liner may protect the conductive lines from one or more subsequent etch operations, such as selective etch operation(s), etc. In some embodiments, the protective oxide liner is a conformal liner deposited on the plurality of conductive lines.

At block 336, a nitride spacer layer is deposited on the protective oxide liners on the conductive lines. The nitride spacer layer may be a metalloid nitride (e.g., silicon nitride) spacer layer. In some embodiments, the nitride spacer layer is a conformal layer deposited on the protective oxide liners.

At block 338, a plurality of gaps between the plurality of conductive lines are filled by depositing an oxide layer. The oxide layer may be a metalloid oxide layer (e.g., a silicon oxide layer, etc.). In some embodiments, the oxide layer is deposited using a deposition process such as CVD or another suitable process.

At block 340, a plurality of air gaps are formed between the plurality of conductive lines by removing the nitride spacer layer. In some embodiments, an etch process is performed to etch the nitride spacer layer. A selective etch process may be performed. For example, a selective etch process may be performed to etch the nitride spacer layer selective to the oxide layer deposited at block 338. The etch process may etch nitride selective to oxide. In some embodiments, the etch process is a hot-phosphorous etch process as described herein. Air gaps may be formed in the voids left by the removed nitride spacer layer. The thickness of the air gaps may be determined by the thickness of the nitride spacer layer. For example, a thicker nitride spacer layer, when removed, may leave larger voids, corresponding to larger air gaps. A thinner nitride spacer layer, when removed, may leave smaller voids, corresponding to smaller air gaps.

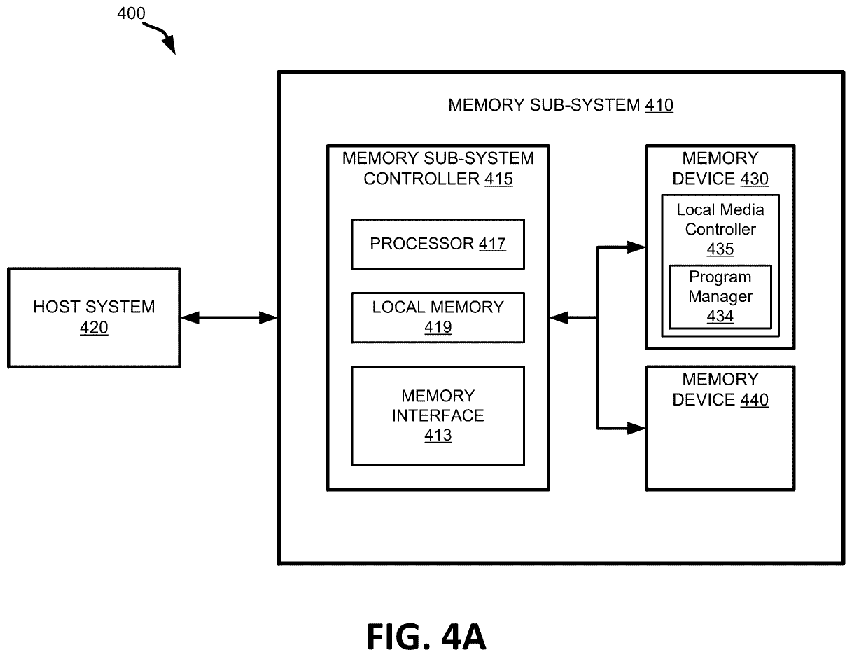

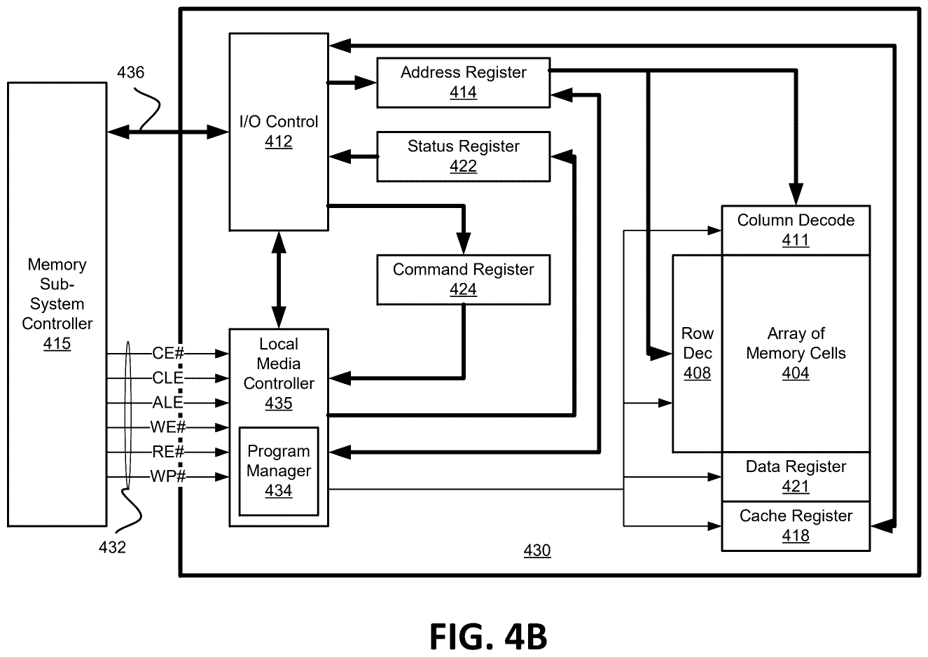

FIG. 4A illustrates an example computing system 400 that includes a memory sub-system 410 in accordance with some embodiments of the present disclosure. In some embodiments, one or more components of computing system 400 include air gaps between conductive lines manufactured according to a method described herein above. The memory sub-system 410 can include media, such as one or more volatile memory devices (e.g., memory device 440), one or more non-volatile memory devices (e.g., memory device 430), or a combination of such.

A memory sub-system 410 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 400 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 400 can include a host system 420 that is coupled to one or more memory sub-systems 410. In some embodiments, the host system 420 is coupled to multiple memory sub-systems 410 of different types. FIG. 4A illustrates one example of a host system 420 coupled to one memory sub-system 410. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 420 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 420 uses the memory sub-system 410, for example, to write data to the memory sub-system 410 and read data from the memory sub-system 410.

The host system 420 can be coupled to the memory sub-system 410 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 420 and the memory sub-system 410. The host system 420 can further utilize an NVM Express (NVMe) interface to access components (e.g., memory devices 430) when the memory sub-system 410 is coupled with the host system 420 by the physical host interface (e.g., PCIe bus). The physical host interface can provide an interface for passing control, address, data, and other signals between the memory sub-system 410 and the host system 420. FIG. 4A illustrates a memory sub-system 410 as an example. In general, the host system 420 can access multiple memory sub-systems via a same communication connection, multiple separate communication connections, and/or a combination of communication connections.

The memory devices 430, 440 can include any combination of the different types of non-volatile memory devices and/or volatile memory devices. The volatile memory devices (e.g., memory device 440) can be random access memory (RAM), such as dynamic random access memory (DRAM) and synchronous dynamic random access memory (SDRAM).

Some examples of non-volatile memory devices (e.g., memory device 430) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 430 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 430 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 430 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 430 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 415 (or controller 415 for simplicity) can communicate with the memory devices 430 to perform operations such as reading data, writing data, or erasing data at the memory devices 430 and other such operations. The memory sub-system controller 415 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 415 can be a microcontroller, special purpose logic circuitry (e.g., a field programmable gate array (FPGA), an application specific integrated circuit (ASIC), etc.), or other suitable processor.

The memory sub-system controller 415 can include a processing device, which includes one or more processors (e.g., processor 417), configured to execute instructions stored in a local memory 419. In the illustrated example, the local memory 419 of the memory sub-system controller 415 includes an embedded memory configured to store instructions for performing various processes, operations, logic flows, and routines that control operation of the memory sub-system 410, including handling communications between the memory sub-system 410 and the host system 420.

In some embodiments, the local memory 419 can include memory registers storing memory pointers, fetched data, etc. The local memory 419 can also include read-only memory (ROM) for storing micro-code. While the example memory sub-system 410 in FIG. 4A has been illustrated as including the memory sub-system controller 415, in another embodiment of the present disclosure, a memory sub-system 410 does not include a memory sub-system controller 415, and can instead rely upon external control (e.g., provided by an external host, or by a processor or controller separate from the memory sub-system).

In general, the memory sub-system controller 415 can receive commands or operations from the host system 420 and can convert the commands or operations into instructions or appropriate commands to achieve the desired access to the memory devices 430. The memory sub-system controller 415 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 430. The memory sub-system controller 415 can further include host interface circuitry to communicate with the host system 420 via the physical host interface. The host interface circuitry can convert the commands received from the host system into command instructions to access the memory devices 430 as well as convert responses associated with the memory devices 430 into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the memory sub-system controller 415 and decode the address to access the memory devices 430.

In some embodiments, the memory devices 430 include local media controllers 435 that operate in conjunction with memory sub-system controller 415 to execute operations on one or more memory cells of the memory devices 430. An external controller (e.g., memory sub-system controller 415) can externally manage the memory device 430 (e.g., perform media management operations on the memory device 430). In some embodiments, memory sub-system 410 is a managed memory device, which is a raw memory device 430 having control logic (e.g., local media controller 435) on the die and a controller (e.g., memory sub-system controller 415) for media management within the same memory device package. An example of a managed memory device is a managed NAND (MNAND) device.

The memory sub-system 410 includes a memory interface component 413 that can handle interactions of memory sub-system controller 415 with the memory devices of memory sub-system 410, such as memory device 430. For example, memory interface component 413 can receive data from memory device 430, such as data retrieved in response to a read operation or a write operation. In some examples, the memory sub-system controller 415 can include a processor 417 (processing device) configured to execute instructions stored in local memory 419 for performing the operations described herein.

In some embodiments, memory device 430 includes a program manager 434. In some embodiments, local media controller 435 includes at least a portion of program manager 434 and is configured to perform various memory functions. In some embodiments, the program manager 434 is part of the host system 410, an application, or an operating system. Further details with regards to the operations of program manager 434 are described below. In some embodiments, program manager 434 is implemented on memory device 430 using firmware, hardware components, or a combination of the above.

FIG. 4B is a simplified block diagram of a first apparatus, in the form of a memory device 430, in communication with a second apparatus, in the form of a memory sub-system controller 415 of a memory sub-system (e.g., memory sub-system 410 of FIG. 4A), according to an embodiment. In some embodiments, one or more components of memory device 430 include air gaps between conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 415 (e.g., a controller external to the memory device 430), can be a memory controller or other external host device.

Memory device 430 includes an array of memory cells 404 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 4B) of at least a portion of array of memory cells 404 are capable of being programmed to one of at least two target data states.

Row decode circuitry 408 and column decode circuitry 411 are provided to decode address signals. Address signals are received and decoded to access the array of memory cells 404. Memory device 430 also includes input/output (I/O) control circuitry 412 to manage input of commands, addresses and data to the memory device 430 as well as output of data and status information from the memory device 430. An address register 414 is in communication with I/O control circuitry 412 and row decode circuitry 408 and column decode circuitry 411 to latch the address signals prior to decoding. A command register 424 is in communication with I/O control circuitry 412 and local media controller 435 to latch incoming commands.

A controller (e.g., the local media controller 435 internal to the memory device 430) controls access to the array of memory cells 404 in response to the commands and generates status information for the external memory sub-system controller 415, i.e., the local media controller 435 is configured to perform access operations (e.g., read operations, programming operations and/or erase operations) on the array of memory cells 404. The local media controller 435 is in communication with row decode circuitry 408 and column decode circuitry 411 to control the row decode circuitry 408 and column decode circuitry 411 in response to the addresses. In at least one embodiment, local media controller 435 includes program manager 434, which can implement the bad block mapping operations with respect to memory device 430, as described herein.

The local media controller 435 is also in communication with a cache register 418. Cache register 418 latches data, either incoming or outgoing, as directed by the local media controller 435 to temporarily store data while the array of memory cells 404 is busy writing or reading, respectively, other data. During a programming operation (e.g., a write operation), data can be passed from the cache register 418 to the data register 421 for transfer to the array of memory cells 404; then new data can be latched in the cache register 418 from the I/O control circuitry 412. During a read operation, data can be passed from the cache register 418 to the I/O control circuitry 412 for output to the memory sub-system controller 415; then new data can be passed from the data register 421 to the cache register 418. The cache register 418 and/or the data register 421 can form (e.g., can form a portion of) a page buffer of the memory device 430. A page buffer can further include sensing devices (not shown in FIG. 4B) to sense a data state of a memory cell of the array of memory cells 404, e.g., by sensing a state of a data line connected to that memory cell. A status register 422 can be in communication with I/O control circuitry 412 and the local memory controller 435 to latch the status information for output to the memory sub-system controller 415.

Memory device 430 receives control signals at the memory sub-system controller 415 from the local media controller 435 over a control link 432. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 432 depending upon the nature of the memory device 430. In at least one embodiment, memory device 430 receives command signals (which represent commands), address signals (which represent addresses), and data signals (which represent data) from the memory sub-system controller 415 over a multiplexed input/output (I/O) bus 436 and outputs data to the memory sub-system controller 415 over I/O bus 436.

For example, the commands can be received over input/output (I/O) pins [7:0] of I/O bus 436 at I/O control circuitry 412 and can then be written into command register 424. The addresses can be received over input/output (I/O) pins [7:0] of I/O bus 436 at I/O control circuitry 412 and can then be written into address register 414. The data can be received over input/output (I/O) pins [7:0] for an 8-bit device or input/output (I/O) pins [15:0] for a 16-bit device at I/O control circuitry 412 and then can be written into cache register 418. The data can be subsequently written into data register 421 for programming the array of memory cells 404.

In at least one embodiment, cache register 418 can be omitted, and the data can be written directly into data register 421. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 430 by an external device (e.g., the memory sub-system controller 415), such as conductive pads or conductive bumps as are commonly used.

In some implementations, additional circuitry and signals can be provided, and that the memory device 430 of FIG. 4B has been simplified. It should be recognized that the functionality of the various block components described with reference to FIG. 4B cannot necessarily be segregated to distinct components or component portions of an integrated circuit device. For example, a single component or component portion of an integrated circuit device could be adapted to perform the functionality of more than one block component of FIG. 4B. Alternatively, one or more components or component portions of an integrated circuit device could be combined to perform the functionality of a single block component of FIG. 4B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming a plurality of conductive lines on a substrate, wherein each of the plurality of conductive lines comprise a metal layer and a nitride layer;
depositing a nitride spacer layer on the plurality of conductive lines;
filling a plurality of gaps between the plurality of conductive lines by depositing a first oxide layer between the plurality of conductive lines; and
forming a plurality of air gaps between the plurality of conductive lines by removing the nitride spacer layer.

2. The method of claim 1, wherein removing the nitride spacer layer comprises:
performing a selective etch operation with respect to the nitride spacer layer, wherein the selective etch operation etches nitride selective to oxide.

3. The method of claim 2, wherein the selective etch operation comprises a hot-phosphorous etch operation performed with respect to the nitride spacer layer.

4. The method of claim 1, further comprising:
forming a doped nitride layer by doping the nitride layer with carbon,.

5. The method of claim 1, further comprising:
depositing protective oxide liners on the plurality of conductive lines, wherein the nitride spacer layer is deposited on the protective oxide liners.

6. The method of claim 5, wherein the protective oxide liners comprise a metalloid oxide having a dielectric constant less than a threshold value.

7. The method of claim 5, further comprising:
performing an anisotropic etch operation with respect to the nitride spacer layer to remove the nitride spacer layer on the substrate between the plurality of conductive lines and to remove the nitride spacer layer on top of the plurality of conductive lines.

8. The method of claim 1, wherein the nitride spacer layer comprises a metalloid nitride and wherein the first oxide layer comprises a metalloid oxide.

9. The method of claim 1, further comprising:
performing a chemical-mechanical planarization process with respect to the first oxide layer and the plurality of conductive lines to reduce an overall height of the plurality of conductive lines and the first oxide layer.

10. The method of claim 1, further comprising:
depositing a second oxide layer on top of the first oxide layer and the plurality of conductive lines, wherein one or more sides of the plurality of air gaps are formed by the first oxide layer, and wherein tops of the plurality of air gaps are formed by the second oxide layer.

11. The method of claim 10, further comprising:
forming multiple metal contacts in the second oxide layer, wherein the multiple metal contacts electrically couple to at least a subset of the plurality of conductive lines.

12. The method of claim 11, further comprising:
etching respective nitride layers from the subset of the plurality of conductive lines, wherein the metal contacts fill respective air gaps of the subset of the plurality of conductive lines and connect to one or more additional metal contacts formed in the substrate.

13. A method, comprising:
forming a plurality of conductive lines on a substrate, wherein each of the plurality of conductive lines comprise a metal layer and a nitride layer;
depositing a protective oxide liner on each of the plurality of conductive lines;
depositing a nitride spacer layer on the protective oxide liners;
filling, by depositing a first oxide layer, a plurality of gaps between the plurality of conductive lines; and
forming a plurality of air gaps between the plurality of conductive lines by removing the nitride spacer layer.

14. The method of claim 13, wherein removing the nitride spacer layer comprises:
performing a selective etch operation with respect to the nitride spacer layer, wherein the selective etch operation etches nitride selective to oxide.

15. The method of claim 13, wherein the protective oxide liners comprise a metalloid oxide having a dielectric constant less than a threshold value.

16. The method of claim 13, further comprising:
depositing a second oxide layer on top of the first oxide layer and the plurality of conductive lines, wherein one or more sides of the plurality of air gaps are formed by the first oxide layer, and wherein tops of the plurality of air gaps are formed by the second oxide layer.

17. The method of claim 16, further comprising:
forming multiple metal contacts in the second oxide layer, wherein the multiple metal contacts electrically couple to at least a subset of the plurality of conductive lines.

18. A memory array, comprising:
a plurality of conductive lines, each of the plurality of conductive lines comprising a metal layer and a nitride layer on top of the metal layer;
a protective oxide liner encapsulating the plurality of conductive lines; and
a first oxide layer between each of the plurality of conductive lines, wherein the first oxide layer forms a plurality of air gaps between the plurality of conductive lines, and wherein each of the plurality of air gaps is at least partially defined by a first surface of the protective oxide liner and a second surface of the first oxide layer.

19. The memory array of claim 18, wherein the nitride layers on top of the metal layers comprise a carbon-doped metalloid nitride.

20. The memory array of claim 18, wherein the protective oxide liner comprises a metalloid oxide having a dielectric constant less than a threshold value.
